(19) United States
(12) Patent Application Publication
(10) Pub. No.: US 2003/0169119 A1
(43) Pub. Date: Sep. 11, 2003

(54) Signal modulation

(76) Inventors: Stephen Goodwin, Cambridgeshire (GB); Ian Appleton, Hertfordshire (GB); Neil Peniket, Cambridge (GB)

Correspondence Address: BANNER & WITCOFF, LTD., TEN SOUTH WACKER DRIVE, SUITE 3000, CHICAGO, IL, 60606, US

(21) Appl. No.: 10/312,183

(22) PCT Filed: Jun. 18, 2001
(86) PCT No.: PCT/GB01/02690

(30) Foreign Application Priority Data
Jun. 20, 2000 (GB) 0015131.6

(51) Int. Cl. H03K 7/08

(52) U.S. Cl. 332/109

(57) ABSTRACT

A control signal (66, 70) for an amplifier (42, FIG. 6) can be switched between a high and a low level to control the shape of the pulse envelope (64, 68) of the amplifier output signal. The duration over which the control signal attains its high level is varied to control the shape of the envelope.

### TECHNICAL FIELD

The invention relates to methods and apparatus for producing a modulated signal. In particular, the invention relates to the production of a pulse envelope defining a burst control profile, such as may define a time slot in a time division multiple access (TDMA) communications system.

FIG. 1 illustrates a transmission channel in a TDMA system. The length of the TDMA frame is T and the particular transmitter using this channel transmits information in a time slot delimited by pulse envelope 10 of duration t. The pulse 10 is also known as the burst control profile.

To ensure that interference caused by the pulse 10 remains within acceptable levels (such as may be specified in a telecommunications standard). The profile of the pulse 10 must fit within a specified mask 20 as shown in FIG. 2.

Maintaining the pulse profile 10 within the mask 20 ensures that transient signals generated around the centre of the transmission channel (indicated 0 MHz in FIG. 3) remain below the acceptable limits specified by curves 30 in FIG. 3. A circuit for controlling the shape of the pulse envelope is shown in FIG. 6. An input signal 40 having a power level Pin is supplied to power amplifier 42 which produces an output signal 44 having power Pout for transmission from an antenna. The power amplifier 42 generates the output signal 44 by modulating the pulse profile of FIG. 1 onto the input signal 40. The output signal 44 is thus constrained to a time slot defined by the burst control profile, i.e. the pulse envelope 10 of FIG. 1. The shape of the pulse envelope applied to the input signal 40 by amplifier 42 is dictated by a power control signal 46 supplied to an input of the amplifier 42.

The power control signal 46 is developed by control circuit 48. Control circuit 48 derives the power control signal 46 from two inputs, one derived from the output of amplifier 44 and the other provided by digital circuitry. The output signal 44 of amplifier 42 is sampled and fed to logarithmic amplifier 50. The logarithmic amplifier 50 provides a logarithmic signal 52 to control circuit 48. The other input to circuit 48 is a control signal 54 which can be thought as the result of the conversion of a digital signal to the analogue domain. The control signal 54 hence may adopt one of a plurality of discrete signal levels.

To produce signal 54 using just a digital to analogue converter would require the use of a high resolution digital to analogue converter (i.e. operating on a digital signal having a relatively large number of bits), in order to provide the control signal 54 with the sufficient resolution to provide the correct definition to the pulse envelope 10. However, a high resolution digital to analogue converter will consume relatively large amounts of energy and silicon area. To avoid this problem, the signal 54 is produced by combining a bi-level signal 56 and a multilevel signal 58. The multilevel signal 58 is provided by the output of a low resolution digital to analogue converter 59 and the bi-level signal 56 is provided by a switch 57 which passes either a high or low level signal. The complexity of the circuit is therefore reduced in that a relatively low resolution digital to analogue converter is used.

In the generation of the control signal 54, the bi-level signal 56 is caused to change between its high and low levels to produce a train of square pulses. The square pulses are of fixed amplitude (signal 54 has only two possible levels) and fixed duration. The square pulses are timed to coincide with substantially the centre of each pulse envelope 10 which defines the time slot. The multi-level signal 58, is controlled to an appropriate level and added to the control signal 54 to control the shaping of the leading and trailing edges of the pulse envelope 10 imposed by power amplifier 42.

The control circuit 48 comprises a differential amplifier 60 having an integrating capacitor 62 connected between its output and its inverting input. The inverting input of the differential amplifier 60 supplied with the logarithmic signal 52 and the non-inverting input is supplied with the control signal 54. The output of the differential amplifier 60 is the power control signal 46 for the power amplifier 42.

In certain TDMA systems, typically those having roaming subscriber units, transmitters can be instructed dynamically to adjust their transmission power levels. For example, when a mobile subscriber unit is near a base station, the base station may instruct the subscriber unit to transmit at a lower power level to save energy in the subscriber unit. The subscriber unit reduces the power of its transmissions by reducing the amplitude of the pulse envelope 10 on its transmission channel. The mask 20 defining the acceptable range of pulse profiles scales up and down in accordance with changes in the height of the pulse 10. When the amplitude of pulse 10 is commanded to adopt a sufficiently low value, the situation arises that the pulse 10 will exceed the limits of the mask 20 by virtue of the use of the square pulses of fixed duration and amplitude within control signal 54.

### DISCLOSURE OF THE INVENTION

According to one aspect, the invention provides apparatus for producing an amplified output signal, comprising means for producing the output signal by amplifying an input signal to impose a pulse envelope thereon, means for controlling the profile of the pulse envelope using a bi-level signal, and means for varying the duration over which the bi-level signal attains its higher level.

According to another, and related aspect, the invention also provides a method of producing an amplified output signal, comprising producing the output signal by amplifying an input signal to impose a pulse envelope thereon, controlling the profile of the pulse envelope using a bi-level signal, and varying the duration over which the bi-level signal attains its higher level.

Thus the invention provides a flexible way of controlling a pulse profile.

In a preferred embodiment, a multi-level signal having a plurality of possible levels is produced by converting a digital signal to the analogue domain and the multi-level signal is combined with the bi-level signal to produce-a control signal for the amplification process.

In one embodiment, the input signal is modulated by a power amplifier, and the output signal is for supplied to an antenna for transmission. The bi-level signal may attain its higher level for substantially a middle portion of the pulse envelope's duration. The pulse envelope may be repeated and may signify a time slot in a time division multiplexing (TDM) communications system.

The purpose of controlling the profile of the pulse envelope may be to fit the profile within a desired range, such as a mask dictating an acceptable range of pulse profiles.

Advantageously, when the peak of the envelope is relatively low, the duration over which the bi-level signal attains its high level is also relatively short.

In one embodiment, the amplification process is controlled by a feedback mechanism. The amplification process may be arranged to use a control signal based on the bi-level signal to modify feedback from the output of the amplification process. The feedback may be provided as a signal which varies as the logarithm of the amplified output signal. The feedback mechanism may comprise means, such as a differential amplifier, for differencing the feedback and control signals.

### DESCRIPTION OF THE DRAWINGS

By way of example only, the invention will now be described with reference to the accompanying figures, in which:

FIG. 1 illustrates the power envelope of a transmitter in a TDMA environment;

FIG. 2 illustrates a pulse in relation to a mask;

FIG. 3 illustrates a transient signal mask;

FIG. 4 illustrates the construction of a pulse;

FIG. 5 illustrates the construction of another pulse; and

FIG. 6 illustrates a power amplifying circuit for imposing a pulse envelope on transmitted signals.

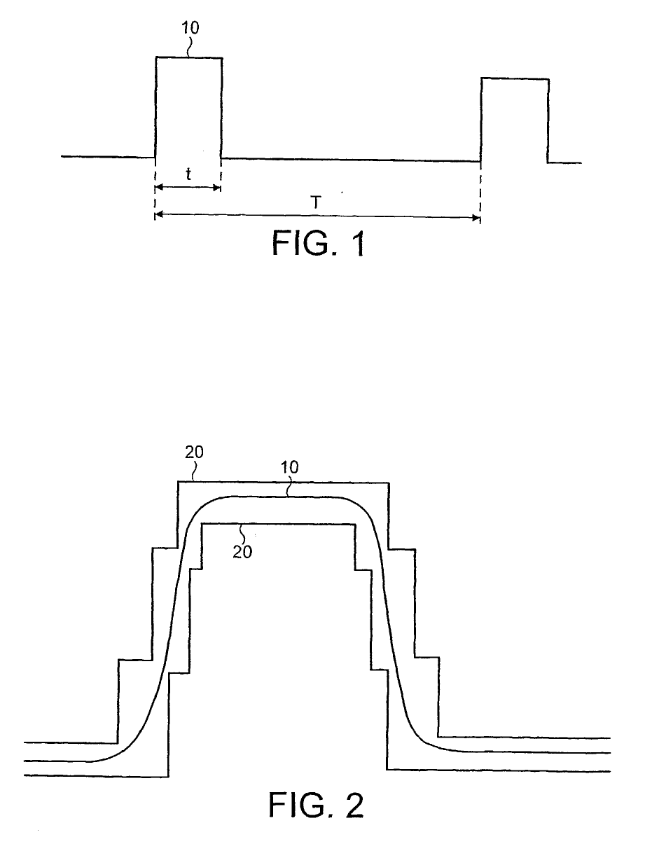

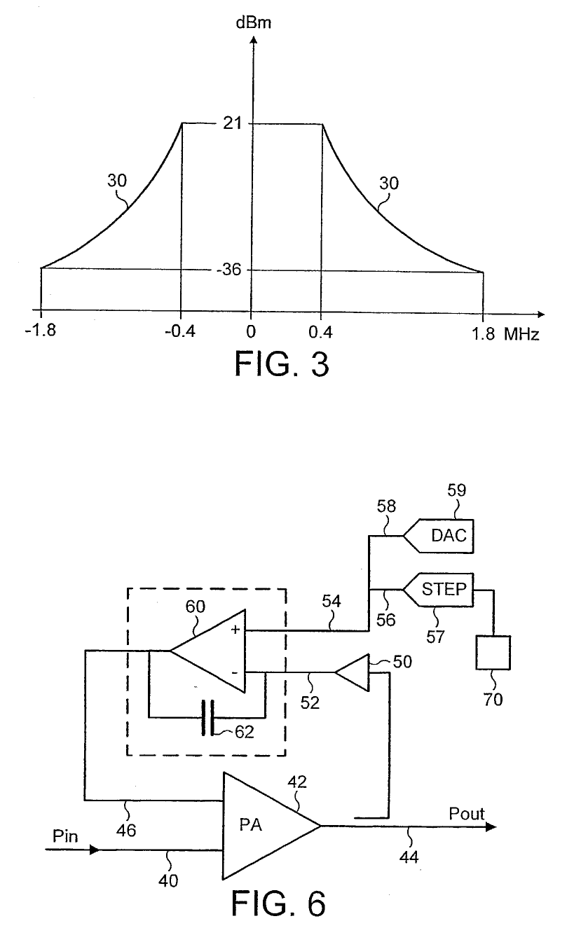

### BEST MODE OF CARRYING OUT THE INVENTION

A transmitter according to an embodiment of the invention uses the power amplifying circuit of FIG. 6 which was described in detail earlier. Unlike the conventional arrangement, the duration of the square pulses within the control signal 54 is variable.

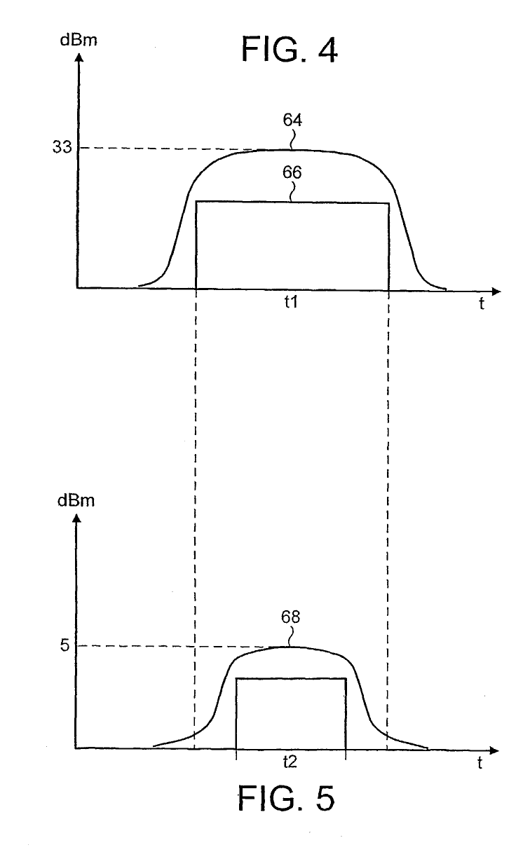

FIG. 4 shows a transmission pulse envelope 64 of height 33 dBm. Superimposed upon this trace, is the square pulse 66 of the bi-level signal 56 responsible for controlling the shape of pulse 64 so that it meets the requisite mask. This square pulse 66 has a duration t1.

When a subscriber unit approaches a base station, it can transmit at a lower level, and this is indicated in FIG. 5, where the height of the pulse envelope 68 in the transmission channel is only 5 dBm. If the pulse envelope 68 was generated by the conventional approach using fixed duration square pulses in control signal 54, then the shape of envelope 68 would be such that it would infringe the mask for a 5 dBm pulse. However, in the present embodiment, when the transmission pulse envelope is to be reduced, the duration of the square pulses 66 provided in bi-level signal 56 is also reduced to t2 so that the pulse profile remains within its mask.

Of course, if the size of the pulse envelope is increased, the duration of the square pulses 66 in bi-level signal 56 are increased to maintain the pulse profile within its mask.

Variation of the duration of the square pulses 66 is effected through switch controller means 70.

1. Apparatus for producing an amplified output signal (Pₒᵤₜ) comprising means (42) for producing the output signal by amplifying an input signal (Pᵢₙ) to impose a pulse envelope (64, 68) thereon, means (57) for controlling the profile of the pulse envelope using a bi-level signal (56), and means (70) for varying the duration (t) over which the bi-level signal (56) attains its higher level.

2. Apparatus according to claim 1, wherein the varying means comprises means (70) for reducing the said duration (t) when the height of the envelope (64, 68) is to be reduced.

3. Apparatus according to claim 1 or 2, comprising means (70) for increasing the said duration (t) when the height of the envelope (64, 68) is to be increased.

4. Apparatus according to any one of claims 1 to 3, comprising means for adjusting said duration (t) to fit said envelope (64, 68) within a range of acceptable profiles.

5. Apparatus according to any preceding claim, comprising means (59) for producing a multi-level signal (58) having one of a plurality of possible levels and means (54) for combining the multi-level and bi-level signals in the control of the profile of said envelope (64, 68).

6. Apparatus according to any preceding claims, comprising feedback means (50, 52, 60, 46) for using the output signal (Pₒᵤₜ) in the control of the profile of the envelope (64, 68).

7. A method of producing an amplified output signal (Pₒᵤₜ), comprising producing the output signal by amplifying an input signal (Pᵢₙ) to impose a pulse envelope (64, 68) thereon, controlling the profile of the pulse envelope using a bi-level signal (56), and varying the duration over which the bi-level signal (56) attains its higher level.

8. A method according to claim 7, comprising reducing the said duration (t) when the height of the envelope (64, 68) is to be decreased.

9. A method according to claim 7 or 8, comprising increasing the said duration (t) when the height of the envelope (64, 68) is to be increased.

10. A method according to any one of claims 7 to 9, comprising adjusting said duration (t) to fit said envelope (64, 68) within a range of acceptable profiles.

11. A method according to any one of claims 7 to 10, comprising producing a multi-level signal (58) having one of a plurality of possible levels and combining the multi-level (58) and bi-level signals (56) in the control of the profile of the envelope (64, 68).

12. A method according to any one of claims 7 to 11, comprising using the output signal (Pₒᵤₜ) as feedback in the control the profile of the envelope (64, 68).

13. Signal transmitting apparatus for transmitting a pulsed signal (Pᵢₙ), comprising the apparatus of any one of claims 1 to 6 for shaping the profiles of the pulses in the transmitted signal.

14. Apparatus according to claim 13, comprising means for determining if the transmission power should be adjusted and wherein the varying means adjusts the said duration responsively.

15. A method of transmitting a pulsed signal, comprising shaping the transmitted pulses using the method of any one of claims 7 to 12.

16. A method of transmitting a pulsed signal according to claim 15, comprising determining if the transmission power should be adjusted and varying said duration responsively.
